(19) United States
(12) Patent Application Publication
(10) Pub. No.: US 2025/0337409 A1
(43) Pub. Date: Oct. 30, 2025

(54) BIAS CIRCUIT FOR BIDIRECTIONAL SWITCH DRIVER

(71) Applicant: TEXAS INSTRUMENTS INCORPORATED, Dallas, TX (US)

(72) Inventors: Kang Wei, Plano, TX (US); Zhikai Tang, Sunnyvale, CA (US); Timothy Merkin, Princeton, TX (US); Shailendra Baranwal, Murphy, TX (US)

(21) Appl. No.: 18/651,017

(22) Filed: Apr. 30, 2024

(51) Int. Cl. H03K 17/687; H01L 29/20; H01L 29/778

(52) U.S. Cl. CPC H03K 17/6871; H10D 30/475; H10D 62/8503

(57) ABSTRACT

An integrated circuit includes a driver circuit having a driver input, a driver output, a power terminal, and a reference terminal; and a bias circuit having a first terminal, a second terminal, a bias control terminal, and a bias output. The bias output is coupled to the reference terminal. The bias circuit includes a first transistor coupled between the first terminal and the bias output, and a second transistor coupled between the bias output and the second terminal. The first transistor has a first control terminal, the second transistor has a second control terminal, and the first control terminal and the second control terminal are coupled to the bias control terminal to receive a same control signal from the bias control terminal.

### BACKGROUND

A bidirectional switch can support bidirectional current flow between two switch terminals when it is in the enabled state and can provide bidirectional voltage blocking between the two switch terminals when it is in the disabled state. A bidirectional switch may include one or more transistors coupled in series across the two switch terminals, and the voltage(s) at the control terminal(s) (e.g., gate(s)) of the one or more transistors can set the enabled/disabled state of the bidirectional switch.

### SUMMARY

This Summary is provided to introduce examples of disclosed concepts in a simplified form, which are further described below in the Detailed Description including the drawings provided.

According to certain aspects, an integrated circuit may include a driver circuit having a driver input, a driver output, a power terminal, and a reference terminal; and a bias circuit having a first terminal, a second terminal, a bias control terminal, and a bias output. The bias output may be coupled to the reference terminal. The bias circuit may include a first transistor coupled between the first terminal and the bias output and a second transistor coupled between the bias output and the second terminal. The first transistor may have a first control terminal, and the second transistor may have a second control terminal, where the first control terminal and the second control terminal may be coupled to the bias control terminal to receive a same control signal from the bias control terminal.

According to certain aspects, an integrated circuit may include a bi-directional switch coupled between a first terminal and a second terminal and having a switch control terminal; a driver circuit having a reference terminal and a driver output that is coupled to the switch control terminal; and a bias circuit coupled between the first terminal and the second terminal and having a bias output coupled to the reference terminal, where the bi-directional switch and the bias circuit may be on a same semiconductor die.

According to certain aspects, an integrated circuit may include a driver circuit for driving a bidirectional switch between a first terminal and second terminal. The driver circuit may include a reference terminal and a driver output. The integrated circuit may also include a bias circuit including a first switch circuit between the first terminal and the reference terminal and a second switch circuit between the reference terminal and the second terminal. The first switch circuit and the second switch circuit may be controlled by a same control signal to electrically couple the reference terminal to a lower voltage level of two voltage levels at the first terminal and the second terminal.

The foregoing summary outlines rather broadly various features of examples of the present disclosure so that the following detailed description may be better understood. Additional features and advantages of such examples will be described hereinafter. This summary is neither intended to identify key or essential features of the claimed subject matters, nor is it intended to be used in isolation to determine the scope of the claimed subject matters. The subject matters should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1A is a schematic of an example of a bidirectional switch including two transistors connected back-to-back.

FIG. 1B is a schematic of an example of a bidirectional switch including two transistors connected back-to-back.

FIG. 2A is a cross-sectional view of an example of a monolithic dual-gate bidirectional switch.

FIG. 2B is a cross-sectional view of an example of a monolithic dual-gate bidirectional switch.

FIG. 3A illustrates an example of an integrated circuit that includes a single-gate bidirectional switch and circuits for controlling the bidirectional switch.

FIG. 3B illustrates a schematic and a symbol representing the example of the single-gate bidirectional switch of FIG. 3A.

FIG. 4A is a schematic of an example of a circuit including a bidirectional switch and circuits for controlling the bidirectional switch.

FIG. 4B is a schematic illustrating an example of an operation of the circuit of FIG. 4A.

FIG. 4C is a schematic illustrating an example of an operation of the circuit of FIG. 4A.

FIG. 5A is a schematic of an example of a circuit including a bidirectional switch and circuits for controlling the bidirectional switch.

FIG. 5B is a schematic illustrating examples of operations of the circuit of FIG. 5A.

FIG. 6A includes a graph illustrating examples of simulated waveforms of some signals of the integrated circuit of FIG. 5A during switching operations.

FIG. 6B is a zoom-in view of the simulated waveforms of FIG. 6A in a time period when the bidirectional switch is turned off.

FIG. 6C is a zoom-in view of the simulated waveforms of FIG. 6A in a time period when the voltage difference between the two terminals of the bidirectional switch increases quickly.

FIG. 6D is a zoom-in view of the simulated waveforms of FIG. 6A in a time period when the bidirectional switch is turned on.

FIG. 7 is a schematic of an example of a circuit including a bidirectional switch and circuits for controlling the bidirectional switch.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to integrated circuits. In some examples, an integrated circuit for driving a transistor-based bidirectional switch may include a driver circuit and a bias circuit. The transistor-based bidirectional switch may include, for example, one or more gallium nitride (GaN)-based high electron mobility transistors (HEMTs). The HEMTs are coupled in series and share a source. In some examples, to reduce the on-state (or enabled state) resistance of the bidirectional switch, the gates of the HEMTs can be positioned close to each other, and no electrical contact is provided for the shared source. In some examples, the bidirectional switch may be a single-gate bidirectional switch with a phantom (or virtual) source that may not physically exist and thus may not be accessible.

The driver circuit may have a driver input, a reference terminal, and a driver output coupled to the control terminal (e.g., a gate) of the transistor-based bidirectional switch. The bias circuit may be used to set an appropriated bias level (e.g., a virtual source voltage level) at the reference terminal of the driver circuit so that the output of the driver circuit can properly turn on or off the bidirectional switch. In one example, the bias circuit may include two transistors connected back-to-back and controlled by the output of the driver circuit to provide an output voltage level that may be equal to or close to the voltage level at a virtual source of the transistor-based bidirectional switch to bias the driver circuit.

The two transistors of the bias circuit may be small GaN-based HEMTs, and thus can be monolithically integrated with bidirectional switches implemented using GaN-based HEMTs and may only use a small semiconductor area. The bias circuit has a relatively simple structure and has no additional control circuits that may consume static current. In some examples, the integrated circuit may include additional circuits to ensure that the bidirectional switch is fully turned off even if the voltage level at a terminal of the bidirectional switch changes at a fast rate (e.g., having a large dV/dt). Other benefits and advantages may also be achieved, such as low on-state resistance, low power loss, smaller devices, and the like, as described in more detail below.

A GaN-based HEMT may include a heterojunction formed by a channel layer (e.g., a GaN layer) and a barrier layer (e.g., an aluminum gallium nitride (AlGaN) layer). High-density two-dimensional electron gas (2DEG) can be formed at the heterojunction to function as a conductive channel. For example, the 2DEG can have a sheet charge density greater than about 10¹³ cm⁻², and thus can have a low static on-state resistance. GaN-based HEMTs are attractive for high frequency and high power applications due to, for example, the high breakdown field, high electron mobility, low static resistance, and high thermal conductivity of GaN-based HEMTs. For example, due to the possibility of current flowing from drain to source and vice versa in a switched-on HEMT, and the possibility of blocking the current flow from drain to source in a switched-off HEMT, GaN-based HEMTs can be used for bidirectional power switching. Due to the lateral device structure and the nonexistence of body diodes in GaN-based HEMTs, it can be relatively easy to fabricate monolithic bidirectional switches implemented using GaN-based HEMTs. In addition, due to the low static on-state resistance of GaN-based HEMTs, GaN-based bidirectional switches can have low power loss and low voltage drop.

In some examples, a GaN-based bidirectional switch may include two HEMTs connected back-to-back (e.g., with the drains of the two HEMTs connected together or the sources of the two HEMTs connected together) to form a dual-gate bidirectional switch having share a common drain or a common source, thereby reducing the distance between the two terminals of the bidirectional switch and thus the on-state resistance of the bidirectional switch. The two gates of a dual-gate bidirectional switch may be driven by a same switch control signal or two different switch control signals. Due to the existence of two gates, the distance between the two terminals of a dual-gate bidirectional switch may still be relatively long and thus the on-state resistance may be relatively high, and the size of the dual-gate bidirectional switch may be relatively large for medium-voltage and low-voltage applications. Reducing the distance between the two gates may reduce the total length and the on-state resistance of the bidirectional switch, but may cause the common source (or drain) inaccessible. In addition, some dual-gate bidirectional switches (e.g., have a common drain) may need to be controlled using two different switch control signals, which may increase the complexity, size, and cost of a system using the dual-gate bidirectional switch.

In some examples, a GaN-based bidirectional switch may be a single-gate bidirectional switch with a phantom (or virtual) source that may not physically exist and thus may not be accessible. With a single gate structure, the distance between the two terminals of the bidirectional switch can be further reduced. Thus, the single-gate bidirectional switch can have a smaller size and a lower specific on-resistance (R_{SP}) for medium-voltage and low-voltage applications. In addition, a single driver circuit can be used to drive the gate, thereby controlling the bidirectional switch. However, since the phantom (or virtual) source may not physically exist and/or may not be accessible, it can be challenging to monolithically integrate a bias circuit for biasing the gate driver on the die of the single-gate bidirectional switch using the same GaN process. For example, in some examples, a comparator circuit may be used to select a lower voltage level of the two voltages levels at the two terminals of the bidirectional switch as the virtual source voltage for biasing the gate driver circuit. But the comparator circuit may have a high quiescent current, including when the bidirectional switch is turned off, may need a floating power source to operate, may need to be able to operate under high voltages, and may be difficult and expensive to fabricate using GaN processes.

In some examples disclosed herein, a simpler and smaller bias circuit may be used to provide, to a driver circuit, a bias voltage level that is equal to or close to the voltage level at a virtual source of a single-gate bidirectional switch or a dual-gate bidirectional switch with a common source that may not be physically accessible (e.g., when the region between the two gates is small), such that the driver circuit may generate appropriate drive signals for controlling the bidirectional switch. For example, the bias circuit may include a first switch circuit (e.g., a transistor or a diode implemented using a transistor) between a first terminal of the bidirectional switch and a reference terminal of the driver circuit, and may also include a second switch circuit (e.g., a transistor or a diode implemented using a transistor) between the reference terminal of the driver circuit and a second terminal of the bidirectional switch. The first switch circuit and the second switch circuit may be controlled by a same control signal to electrically couple (e.g., with a small voltage drop) the reference terminal of the driver circuit to a terminal of the first terminal or the second terminal that has a lower voltage level. The control signal for controlling the first switch circuit and the second switch circuit may be, for example, the output of the driver circuit or the output (e.g., the bias voltage) of the bias circuit. The first switch circuit and the second switch circuit can be implemented using, for example, small HEMTs, and thus can be monolithically integrated with the bidirectional switch formed by GaN-based HEMTs and would not take a large semiconductor area.

In one example, the bias circuit may include two transistors (e.g., small HEMTs) connected back-to-back and controlled by a delayed output of the driver circuit to provide a bias voltage level that is equal to or close to the voltage level of the virtual source or the common source of the bidirectional switch to bias the driver circuit during steady state. The delayed output of the driver circuit may switch off at least one of the two transistors of the bias circuit after the bidirectional switch have been turned off, such that any charges stored at the bidirectional switch (e.g., at the gate) can be removed through one of the two transistors and the bias voltage can be reduced, thereby ensuring that the bidirectional switch is fully turned off.

In another example, the integrated circuit may include a high-pass circuit between the two terminals of the bidirectional switch to ensure that the bidirectional switch remains in the OFF state when the voltage level at a terminal of the bidirectional switch changes at a fast rate (e.g., with a high dV/dt). The high-pass circuit may include a high-pass filter, and two transistors (e.g., small HEMTs) coupled between the two terminals of the bidirectional switch. When a voltage level at a terminal of the bidirectional switch changes at a fast rate (e.g., with a high dV/dt), the high-pass filter may generate (e.g., via capacitive coupling) a voltage signal to drive the gates of the two transistors, so that at least one of the two transistors may be turned on to provide the lower voltage level at the two terminals of the bidirectional switch to the gate of the bidirectional switch, thereby ensuring that the bidirectional switch remains in the OFF state during a voltage change at a high dV/dt. The high-pass circuit can also provide a current path to remove the charges stored at the high-pass circuit due to the voltage change at the high dV/dt, to ensure that the two transistors of the high-pass circuit are turned off and would not consume power during the steady state.

The bias circuit disclosed herein can be used to provide a virtual source voltage to bias the driver circuit of a bidirectional switch that does not have a source region. The bias circuit disclosed herein can also be used to provide a voltage level that is equal to the voltage level at a common source of a dual-gate bidirectional switch that is not accessible, in order to properly bias the driver circuit of the bidirectional switch. In addition, the bias circuit may have reduced/zero quiescent current when the bidirectional switch is disabled, and would not need a floating power supply. The bias circuit and/or the high-pass circuit disclosed herein can be implemented using small GaN-based HEMTs, thereby enabling the monolithic integration of the bias circuit and/or the high-pass circuit with the bidirectional switch. The two small GaN-based HEMTs of the bias circuit can be controlled by the delayed output of the driver circuit to remove charges stored at the gate of the bidirectional switch, thereby ensuring that the bidirectional switch is fully turned off. The high-pass circuit may include two small GaN-based HEMTs and a high-pass filter to detect positive voltage changes with high dV/dt and keep the bidirectional switch in the OFF state during high dV/dt transitions. In some examples, the bias circuit can be implemented using discrete components or silicon-based devices integrated with the bidirectional switch (e.g., in a same package).

As such, techniques disclosed herein may enable relatively low-cost, monolithic integration of a bidirectional switch with a bias circuit for providing a virtual source voltage level to bias a driver circuit of the bidirectional switch. The bias circuits disclosed herein do not use additional control circuits and consumes little or no quiescent current when the bidirectional switch is disabled, and can be used in applications where the available power for the driver circuit may be limited. Since only small GaN HEMTs, resistors, and/or capacitors are used in the bias circuits and/or high-pass circuits disclosed herein, the bias circuits and/or high-pass circuits can be relatively easily integrated with the bidirectional switch using the same GaN processes. In addition, the single-gate bidirectional switch controlled by a driver circuit that is properly biased using the virtual source voltage generated by the relatively simple bias circuit disclosed herein can have a reduce channel length and thus a low static on-state resistance, a low voltage drop, and a low power loss. The high-pass circuit can detect and handle fast voltage changes with high dV/dt to avoid unintentional switching of the bidirectional switch when the bidirectional switch is in the OFF state, without using transistors with low threshold voltages that may be difficult and expensive to achieve in the bias circuit.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for case of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

Various examples are described in the context of an HEMT. Some examples may be implemented in enhancement mode lateral HEMTs that are for high voltage (e.g., about 650 V to about 1,200 V) applications or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications.

For the sake of illustration, some of the examples disclosed herein may focus on group-III nitride-based devices, such as GaN-based HEMTs. However, this disclosure is not limited to GaN-based HEMTs and can be applied to other devices that include heterostructures formed by other semiconductor materials, such as other group-III nitride or other III-V semiconductor materials, where the heterostructures may induce 2DEG at the heterojunction interface.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

GaN-based HEMTs include heterostructures that may induce two-dimensional electron gas (2DEG) at the interface between two GaN-based materials having different bandgaps. In one example, the heterostructure may be formed by a GaN layer and an AlₓGa₍₁₋ₓ₎N layer, where x is the concentration of aluminum. The GaN layer may have a narrower bandgap than the AlₓGa₍₁₋ₓ₎N layer, which may be referred to as a barrier layer because of its wider bandgap. Due to the bandgap mismatch, large conduction-band offset, and spontaneous and piezoelectric polarization properties of the group-III nitride layers, highly-mobile 2DEG may be generated in the GaN layer near the interface of the heterostructure to form a conductive channel in the GaN layer (which is thus referred to as the channel layer). Compared to silicon-based transistors, GaN-based transistors generally have high breakdown field, high electron mobility, low on-state resistance, high current, faster-switching speed, high thermal conductivity, and excellent reverse-recovery performance, and thus may be more suitable for applications where a low-loss and high-efficiency performance may be desired, such as power electronics (e.g., power switches).

A GaN-based transistor may include a gate structure positioned between a source structure and a drain structure. The drain structure may include a metal contact that may be coupled to the channel layer directly or indirectly (e.g., through tunneling) and may form an ohmic contact with the channel layer. The source structure may include a metal contact that may be coupled to the channel layer directly or indirectly and may form an ohmic contact with the channel layer. Depending on the architecture of the gate structure, a GaN-based transistor may be an enhancement mode high electron mobility transistor (e-HEMT) or a depletion mode high electron mobility transistors (d-HEMT). For example, the gate structure of an e-HEMT may include a p-GaN layer formed over the barrier layer, and a gate electrical contact (a metal electrode) formed on the p-GaN layer, which together form a p-GaN gate structure. The p-GaN layer of the gate structure may be doped with, for example, magnesium (Mg), which is an acceptor that can make the GaN layer p-type or p-doped. The p-GaN layer may deplete electrons in the 2DEG channel under the p-GaN gate structure, such that the conductive path between the source and gate may be disabled and thus the e-HEMT may be turned off when no gate drive voltage is applied to the gate electrical contact. When a positive voltage above the gate threshold voltage is applied to the gate electrical contact, the gate structure may attract electrons to replete the 2DEG under the gate structure, thereby turning on the e-HEMT. In contrast, the gate structure of a d-HEMT may include an insulator layer (e.g., a dielectric layer) over the barrier layer, and a gate electrical contact (e.g., a metal electrode) on the insulator layer. When no voltage signal is applied to the gate electrical contact, the 2DEG under the gate structure may not be depleted such that the conductive path in the channel layer between the drain structure and the source structure may be enabled even without a positive gate voltage. A d-HEMT can be turned off by applying a negative threshold voltage to the gate electrical contact to deplete electrons from the 2DEG under the gate structure. In some applications such as switch-mode power applications (e.g., power switches), e-HEMTs, rather than d-HEMTs, may be used in order to, for example, decrease leakage current, reduce power loss, simplify the driving circuit, and/or improve device stability.

A bidirectional switch can support bidirectional current flow when it is turned on and can provide bidirectional voltage blocking when it is turned off. A bidirectional switch may be used, for example, as a bidirectional power switch for charger multiplexing, where the bidirectional switch may be turned on to charge a battery using a current from a power supply to the battery, or to provide a current from the battery to a load. The bidirectional switch may also be turned off to block current in either direction, for example, to avoid draining a charged battery or prevent one battery from charging another battery. A bidirectional switch may be implemented using two transistors connected back-to-back (e.g., with the drains connected together or with the sources connected together) to form a dual-gate bidirectional switch having a common drain or a common source. The two transistors may be, for example, metal-oxide-semiconductor field effect transistors (MOSFETs) or HEMTs.

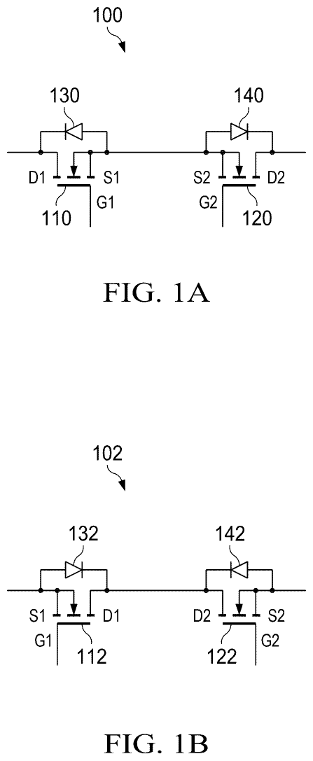

FIG. 1A is a schematic of an example of a bidirectional switch 100 including two transistors connected back-to-back (e.g., having a common source). In the example illustrated in FIG. 1A, bidirectional switch 100 may include a first N-channel MOSFET (N-MOSFET) 110 and a second N-MOSFET 120 connected back-to-back to share a common source. N-channel MOSFETs may have lower resistance than P-channel MOSFETs of similar sizes. A MOSFET may have a low voltage drop between the drain and source when the channel is turned on, and may function as a diode when the channel is turned off (and thus may have a voltage drop equal to about the threshold voltage of the diode in the forward-biasing direction).

When the gate voltage at gate G1 of first N-MOSFET 110 and the gate voltage at gate G2 of second N-MOSFET 120 are set properly (e.g., above the threshold voltage), both first N-MOSFET 110 and second N-MOSFET 120 may be turned on, such that a current may flow from the drain D1 of first N-MOSFET 110 to the drain D2 of second N-MOSFET 120 if the voltage level at drain D1 is higher than the voltage level at drain D2, or may flow from drain D2 of second N-MOSFET 120 to drain D1 of first N-MOSFET 110 if the voltage level at drain D2 is higher than the voltage level at drain D1. When both the first N-MOSFET 110 and second N-MOSFET 120 are turned on, the total voltage drop at first N-MOSFET 110 and second N-MOSFET 120 may be low (e.g., close to zero).

When only one of first N-MOSFET 110 and second N-MOSFET 120 is turned on, a current may be able to flow in one direction if the voltage difference between drain D1 and drain D2 is high, but may be blocked from flowing in the opposite direction because the diode structure (e.g., diode structure 130 or 140) formed by the MOSFET that is turned off may only allow the current to flow from the source to drain (forward biased) and may block the current from the drain to source (reverse biased). In addition, even though the current may be allowed to flow in one direction, the voltage drop at the MOSFET that is turned off may be high (e.g., at about the threshold voltage of the diode structure) due to the non-zero threshold voltage of the diode structure. For example, when first N-MOSFET 110 is turned on and second N-MOSFET 120 is turned off, a current may be allowed to flow from drain D1 to drain D2 and the voltage drop between drain D1 and drain D2 may be close to the threshold voltage of the forward biased diode structure 140 formed by second N-MOSFET 120 that is turned off, but a current may not be allowed to flow from drain D2 to drain D1 due to the reverse biased diode structure 140 formed by second N-MOSFET 120 that is turned off.

When both first N-MOSFET 110 and second N-MOSFET 120 are turned off, no current (or an insignificant amount of current) may be allowed to flow between drain D1 and drain D2 because a current in either direction may be blocked by a reverse biased diode. For example, a current from drain D1 to drain D2 may be blocked by the reverse biased diode structure 130 formed by the turned-off first N-MOSFET 110, while a current from drain D2 to drain D1 may be blocked by the reverse biased diode structure 140 formed the turned-off second N-MOSFET 120.

FIG. 1B is a schematic of another example of a bidirectional switch 102 including two transistors connected back-to-back (e.g., at a common drain). In the example shown in FIG. 1B, bidirectional switch 102 may include a first N-MOSFET 112 and a second N-MOSFET 122 connected back-to-back to share a common drain. As described above, N-channel MOSFETs may have lower resistance than P-channel MOSFETs of similar sizes, and thus are more suitable for use in power switches. A MOSFET may have a low voltage drop between the drain and source when the channel is turned on, but may function as a diode when the channel is turned off (and thus may have a voltage drop equal to about the threshold voltage of the diode in the forward-biasing direction).

When the gate voltage at gate G1 of first N-MOSFET 112 and the gate voltage at gate G2 of second N-MOSFET 122 are set properly (e.g., above the threshold voltage) to turn on both first N-MOSFET 112 and second N-MOSFET 122, a current may flow from source S1 of first N-MOSFET 112 to source S2 of second N-MOSFET 122 if the voltage level at source S1 is higher than the voltage level at source S2, or may flow from source S2 of second N-MOSFET 122 to source S1 of first N-MOSFET 112 if the voltage level at source S2 is higher than the voltage level at source S1. The total voltage drop at first N-MOSFET 112 and second N-MOSFET 122 that are turned on may be low (e.g., close to zero).

When only one of first N-MOSFET 112 and second N-MOSFET 122 is turned on, a current may be able to flow in one direction, but may be blocked from flowing in the opposite direction because the diode structure formed the MOSFET that is turned off may only allow the current to flow from the source to the drain (forward biased) and may block the current from the drain to source (reverse biased). In addition, even though a current may be allowed to flow in one direction, the voltage drop at the MOSFET that is turned off may be close to the threshold voltage of the diode structure. For example, when first N-MOSFET 112 is turned on and second N-MOSFET 122 is turned off, a current may be allowed to flow from source S2 to source S1 and the voltage drop between source S2 and source S1 may be close to the threshold voltage of a forward biased diode structure 142 formed by second N-MOSFET 122 that is turned off, but a current may not be allowed to flow from source S1 to source S2 due to the reverse biased diode structure 142 formed by second N-MOSFET 122 that is turned off.

When both first N-MOSFET 112 and second N-MOSFET 122 are turned off, no current (or an insignificant amount of current) may be allowed to flow between source S1 and source S2 because a current in either direction may be blocked by a reverse biased diode. For example, a current from source S1 to source S2 may be blocked by the reverse biased diode structure 142 formed by the turned-off second N-MOSFET 122, while a current from source S2 to source S1 may be blocked by a reverse biased diode structure 132 of the turned-off first N-MOSFET 112.

As described above, compared to silicon-based transistors, GaN-based HEMTs may have high breakdown field, high electron mobility, low on-state resistance, high current, faster-switching speed, high thermal conductivity, and excellent reverse-recovery performance, and thus may be more suitable for applications where a low-loss and high-efficiency performance may be desired, such as power electronics or radio frequency (RF) circuits. A GaN-based HEMT may allow current to flow from the drain to source and vice versa when the HEMT is turned on (in the ON state), may block the current flow from the drain to source when the HEMT is turned off (in the OFF state), and may have lower static on-state resistance (and thus lower voltage drop and lower power loss) than MOSFETs due to, for example, the high electron mobility. Therefore, GaN-based HEMTs may be suitable for use in bidirectional switches and may offer higher switching speed and lower power loss and voltage drop. In addition, due to the lateral device structure and the nonexistence of body diodes in GaN-based HEMTs, it can be relatively easy to fabricate monolithic bidirectional switches implemented using GaN-based HEMTs. In some examples, a GaN-based bidirectional switch may include two HEMTs connected back-to-back to form a dual-gate bidirectional switch having a common drain or a common source, thereby reducing the distance between the two terminals of the bidirectional switch and thus the on-state resistance. The two gates may be driven by a same switch control signal or two different switch control signals.

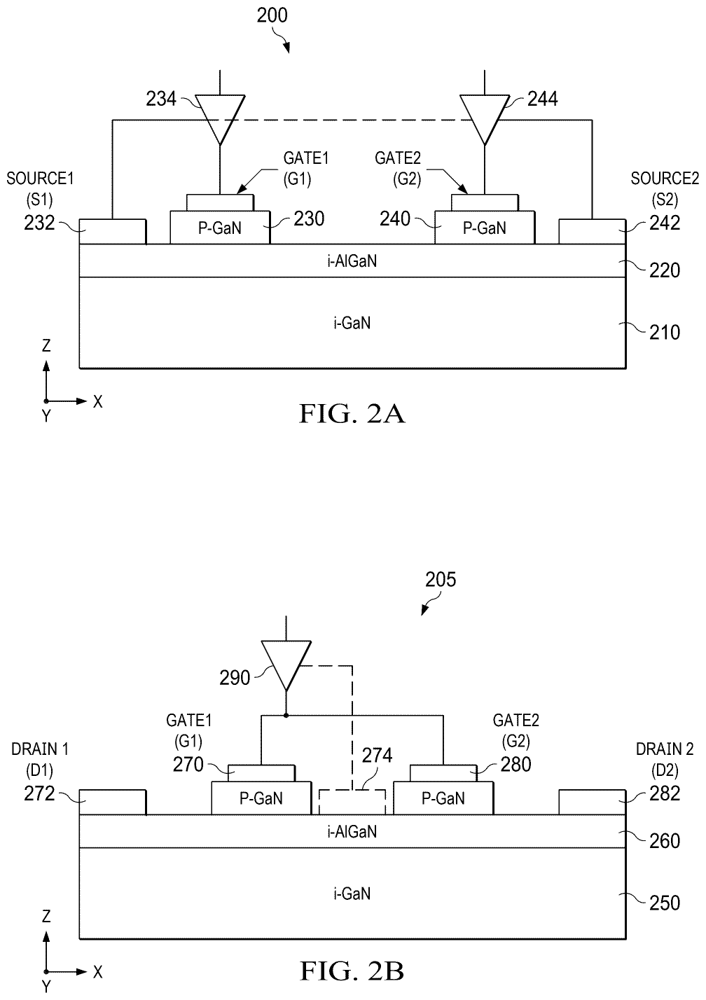

FIG. 2A is a cross-sectional view of an example of a monolithic dual-gate bidirectional switch 200. Bidirectional switch 200 may be implemented using GaN-based HEMTs. In the illustrated example, bidirectional switch 200 includes two enhancement mode HEMTs that are connected back-to-back to share a common drain. Bidirectional switch 200 may include a substrate (not shown), a channel layer 210 (e.g., including an undoped GaN layer) grown on the substrate, and a barrier layer 220 (e.g., including an undoped AlₓGa₍₁₋ₓ₎N layer) over channel layer 210. The GaN material in channel layer 220 has a narrower bandgap than the AlₓGa₍₁₋ₓ₎N material in barrier layer 220. Due to the bandgap mismatch, large conduction-band offset, and spontaneous and piezoelectric polarization properties of the group-III nitride layers, highly-mobile 2DEG may be generated in channel layer 210 near the interface of the heterostructure to form a conductive channel in channel layer 210.

A first gate structure 230 and a second gate structure 240 may be formed over barrier layer 220. Each of first gate structure 230 and second gate structure 240 may include a p-GaN layer formed over barrier layer 220 and a gate electrical contact (e.g., a metal gate electrode) formed on the p-GaN layer, which together form a p-GaN gate structure. The p-GaN layer may be a GaN layer doped with, for example, magnesium (Mg). The p-GaN layer may deplete electrons in the 2DEG channel under the p-GaN gate structure, such that the path between the source and drain may be disabled when no gate drive voltage is applied to the gate electrical contact. When a positive voltage above the gate threshold voltage is applied to the gate electrical contact, the gate structure may attract electrons to replete the 2DEG under the gate structure, thereby turning on the enhancement mode HEMT. A first source structure 232 and a second source structure 242 may be formed on or in barrier layer 220. The common drain of the two HEMTs may not need to be accessed, and thus there may not need to be a drain structure formed over barrier layer 220. The source and gate structures may be electrically isolated by one or more dielectric layers and may be accessible through interconnects formed in the dielectric layers.

In the example shown in FIG. 2A, first gate structure 230 of the first HEMT may be controlled by a first driver circuit 234, while second gate structure 240 of the second HEMT may be controlled by a second driver circuit 244. First driver circuit 234 may be biased based on the voltage level at, for example, first source structure 232, so that the driver output of first driver circuit 234 may have the appropriate voltage level with respect to first source structure 232 to properly turn on the first HEMT (e.g., when the voltage difference V_{GS} between the gate and the source is equal to or greater than the threshold voltage Vₜₕ) or turn off the first HEMT (e.g., when V_{GS}<V_{GS}). Similarly, second driver circuit 244 may be biased based on the voltage level at, for example, second source structure 242, so that the driver output of second driver circuit 244 may have the appropriate voltage level with respect to second source structure 242 to properly turn on the second HEMT (e.g., when V_{GS}≥Vₜₕ) or turn off the second HEMT (e.g., when V_{GS}<Vₜₕ). In some examples, first driver circuit 234 and second driver circuit 244 may be biased based on the same voltage level, such as the voltage level at first source structure 232 or second source structure 242.

As described above with respect to FIGS. 1A and 1B, when both the first HEMT and the second HEMT are turned on, bidirectional switch 200 may be turned on and may have low resistance and low voltage drop between first source structure 232 and second source structure 242. In addition, since the drain region is shared, the total channel length of bidirectional switch 200 can be shorter than the total channel length of two separate HEMTs, and thus the on-state resistance of bidirectional switch 200 can be reduced. When only one of the first HEMT and the second HEMT is turned on, a current may be allowed to flow in one direction and there may be a voltage drop across the bidirectional switch due to the threshold voltage of the diode structure formed by the HEMT that is not turned on, and a current may not be allowed to flow in the opposite direction because the current may not be allowed to flow from the drain to the source of the HEMT that is not turned on. When both the first HEMT and the second HEMT are turned off, bidirectional switch 200 may be turned off, and may block current flow in both directions because current may not be allowed to flow from the drain to the source of the HEMTs that are not turned on, as described above.

FIG. 2B is a cross-sectional view of another example of a monolithic dual-gate bidirectional switch 205. As bidirectional switch 200, bidirectional switch 205 may be implemented using GaN-based HEMTs. In the illustrated example, bidirectional switch 200 includes two enhancement mode HEMTs that are connected back-to-back and share a common source. Bidirectional switch 205 may include a substrate (not shown), a channel layer 250 (e.g., including an undoped GaN layer) grown on the substrate, and a barrier layer 260 (e.g., including an undoped AlₓGa₍₁₋ₓ₎N layer) over channel layer 250. Due to the bandgap mismatch, large conduction-band offset, and spontaneous and piezoelectric polarization properties of the group-III nitride layers, highly-mobile 2DEG may be generated in channel layer 250 near the interface of the heterostructure to form a conductive path in channel layer 250.

A first gate structure 270 and a second gate structure 280 may be formed over barrier layer 260. Each of first gate structure 270 and second gate structure 280 may include a p-GaN layer formed over barrier layer 260 and a gate electrical contact (e.g., a metal gate electrode) formed on the p-GaN layer, which together form a p-GaN gate structure. The p-GaN layer may deplete electrons in the 2DEG channel under the p-GaN gate structure, such that the path between the source and drain may be disabled when no gate drive voltage is applied to the gate electrical contact. When a positive voltage above the gate threshold voltage is applied to the gate electrical contact, the gate structure may attract electrons to replete the 2DEG under the gate structure, thereby turning on the enhancement mode HEMT. A first drain structure 272 and a second drain structure 282 may be formed on or in barrier layer 260. In some examples, a common source structure 274 may be formed on or in barrier layer 260. In some examples, to reduce the size and the on-state resistance of bidirectional switch 205, the common source region may be small and no common source structure may be formed in bidirectional switch 205. The gate, drain, and source (if formed) structures may be electrically isolated by one or more dielectric layers and may be accessible through interconnects formed in the dielectric layers. To support high voltage stress between the drain and the gate of each HEMT, the distance between first gate structure 270 and first drain structure 272 can be longer than the distance between first gate structure 270 and common source structure 274, and the distance between second gate structure 280 and second drain structure 282 can be longer than the distance between second gate structure 280 and common source structure 274.

In the example shown in FIG. 2B, first gate structure 270 of the first HEMT and second gate structure 280 of the second HEMT may be controlled by a same driver circuit 290. Driver circuit 290 may be biased based on the voltage level at common source structure 274, so that the driver circuit 290 may generate output signals having the appropriate voltage levels with respect to common source structure 274 to properly turn on the first HEMT and the second HEMT (e.g., when the voltage difference V_{GS} between the gate and the source is equal to or greater than the threshold voltage Vₜₕ) or turn off the first HEMT and the second HEMT (e.g., when V_{GS}<Vₜₕ). In some examples, a lower voltage level of the two different voltage levels at first drain structure 272 and second drain structure 282 may be selected to bias driver circuit 290 because the voltage difference between the common source and the drain of an HEMT that is turned on may be small due to the low on-state resistance of the HEMT.

As described above, when both the first HEMT and the second HEMT are turned on, bidirectional switch 205 may be turned on and may have low resistance and low voltage drop between first drain structure 272 and second drain structure 282. In addition, since the source region is shared, the total channel length of bidirectional switch 205 can be shorter than the total channel length of two separate HEMTs, and thus the on-state resistance of bidirectional switch 205 can be reduced. When both the first HEMT and the second HEMT are turned off, bidirectional switch 205 may be turned off, and may block current flow in both directions because a current may not be allowed to flow from the drain to the source of the HEMTs that are not turned on, as described above.

Due to the existence of the two gate structures in dual-gate bidirectional switch 200 or 205, the distance between the two terminals of the bidirectional switch may still be relatively long and thus the on-state resistance may be relatively high, and the size of the bidirectional switch may still be relatively large for medium-voltage and low-voltage applications. In addition, some dual-gate bidirectional switches, such as bidirectional switch 200, may need to be controlled using two driver circuits. According to some examples, a GaN-based bidirectional switch may include a single-gate bidirectional switch with a phantom (or virtual) common source. With a single gate structure, the distance between the two terminals of the bidirectional switch can be further reduced. Thus, the single-gate bidirectional GaN switch can have a smaller size and a lower specific on-resistance (R_{SP}) for medium-voltage and low-voltage applications. In addition, a single driver circuit can be used to drive the gate to control the bidirectional switch.

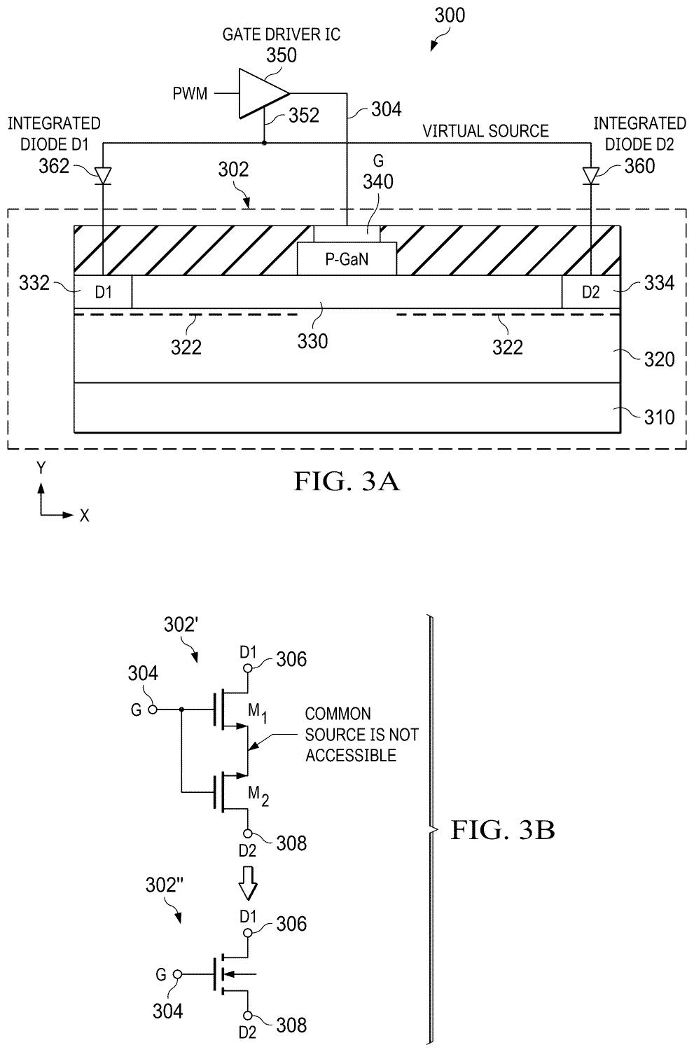

FIG. 3A illustrates an example of an integrated circuit 300 that includes a single-gate bidirectional switch 302 and circuits for controlling bidirectional switch 302. Integrated circuit 300 may include one semiconductor die or two or more semiconductor dies. FIG. 3A shows an example of a cross-sectional view of bidirectional switch 302 that may be implemented using GaN-based HEMTs. As illustrated, bidirectional switch 302 may include a substrate 310, such as a bulk semiconductor substrate, a semiconductor-on-insulator (SOI) substrate, or another suitable substrate (e.g., a Qromis Substrate Technology (QST) substrate, a sapphire substrate, or another silicon-based substrate). Bidirectional switch 302 may include a channel layer 320 (e.g., including an undoped GaN layer) grown on substrate 310, and a barrier layer 330 (e.g., including an undoped AlₓGa₍₁₋ₓ₎N layer) over channel layer 320. Due to the bandgap mismatch, large conduction-band offset, and spontaneous and piezoelectric polarization properties of the group-III nitride layers, highly-mobile 2DEG 322 may be generated in channel layer 320 (near the interface of the heterostructure) to form a conductive channel in channel layer 320.

A first drain structure 332 and a second drain structure 334 may be formed on or in barrier layer 330. A gate structure 340 may also be formed over barrier layer 330. Gate structure 340 may include a p-GaN layer formed over barrier layer 330 and a gate electrical contact (e.g., a metal gate electrode) formed on the p-GaN layer, which together form a p-GaN gate structure. The p-GaN layer may be a GaN layer doped with, for example, magnesium (Mg), and may deplete electrons in 2DEG 322 under gate structure 340, such that the path between first drain structure 332 and second drain structure 334 may be disabled and bidirectional switch 302 may be turned off when no gate drive voltage is applied to the gate electrical contact. When a positive voltage above the gate threshold voltage is applied to the gate electrical contact, gate structure 340 may attract electrons to replete the 2DEG under the gate structure, thereby turning on bidirectional switch 302. First drain structure 332, second drain structure 334, and gate structure 340 may be electrically isolated by one or more dielectric layers and may be accessible through interconnects formed in the dielectric layers.

As shown in FIG. 3A, in single-gate bidirectional switch 302, the common source region may be reduced to zero and the two gate structures as shown in FIGS. 2A and 2B may be merged into a common gate structure (e.g., gate structure 340). Therefore, bidirectional switch 302 may only have one gate terminal (which may be the control terminals of the bidirectional switch) and two drain terminals (which may be the input/output terminals of the bidirectional switch), and the total channel length can be reduced significantly to reduce the on-state resistance. The gate terminal may be coupled to gate structure 340 and a driver circuit 350, which may provide control signals to turn on or off bidirectional switch 302.

FIG. 3B illustrates a schematic 302′ and a symbol 302″ representing the example of single-gate bidirectional switch 302 of FIG. 3A. As illustrated, single-gate bidirectional switch 302 may have three terminals that include a control terminal 304 (e.g., a gate terminal), a first switch terminal 306 (which may be an input and/or output terminal), and a second switch terminal 308 (which may be an input and/or output terminal). Single-gate bidirectional switch 302 may not have a physical source region or source terminal, and thus the common source may be phantom or virtual. Single-gate bidirectional switch 302 may be represented by a schematic 302′ that includes two transistors connected back-to-back to share a virtual common source. To distinguish single-gate bidirectional switch 302 from a dual-gate bidirectional switch that has two gate structures controlled by a same driver circuit (e.g., bidirectional switch 205 shown in FIG. 2B), a symbol 302″ that may have three terminals as shown in FIG. 3B may be used to represent single-gate bidirectional switch 302.

As described above, driver circuit 350 may need to be biased to a reference voltage at a reference terminal 352 in order to provide the appropriate output voltage levels to gate structure 340 to switch bidirectional switch 302. However, a source may not be accessible (e.g., due to omission of electrical contact to reduce the distance between two gate structures), or may not physically exist (e.g., the phantom source of FIG. 3A) in bidirectional switch 302, and either first drain structure 332 or second drain structure 334 may have a lower voltage level in bidirectional switching applications. Therefore, it can be challenging to bias the driver circuit of single-gate bidirectional switch 302 or dual-gate bidirectional switch that may not have physical access to a source structure. In some examples, a comparator circuit may be used to select a lower voltage level of the two voltages levels at the two terminals of the bidirectional switch as the virtual source voltage for biasing the gate driver circuit. However, the comparator circuit may have a high quiescent current, may need a floating power source to operate, and may need to be able to operate under high voltages. In addition, the comparator circuit may be difficult and expensive to implement using GaN processes, and thus may be difficult to be integrated onto the die of single-gate bidirectional switch 302 using the same process.

As shown in FIG. 3A, in some examples, a bias circuit may need to be used to generate a voltage level that may be equal to or close to the (theoretical) voltage level at the virtual source to bias the driver circuit of a single-gate bidirectional GaN switch or a dual-gate bidirectional switch that has no physically accessible common source (e.g., when the region between the two gates is small). For example, in the example shown in FIG. 3A, two diodes 360 and 362 (which may be diodes or may be implemented using, for example, transistors) connected back-to-back at the anodes may be used to connect the reference terminal of driver circuit 350 to a lower voltage level of the two voltage levels at the two switch terminals of bidirectional switch 302. For example, if the voltage level at first drain structure 332 (or first switch terminal 306) is lower than the voltage level at second drain structure 334 (or second switch terminal 308), diode 362 may be turned on first, such that the bias voltage at reference terminal 352 may be equal to the sum of the voltage level at first drain structure 332 (and first switch terminal 306) and the voltage drop across diode 362, and diode 360 may not be turned on. If the voltage level at second drain structure 334 is lower than the voltage level at first drain structure 332, diode 360 may be turned on first, such that the bias voltage at reference terminal 352 may be equal to the sum of the voltage level at second drain structure 334 (and second switch terminal 308) and the voltage drop across diode 360, and diode 362 may not be turned on. When bidirectional switch 302 is turned off, diodes 360 and 362 can be turned off, and the bias voltage at reference terminal 352 may remain unchanged (e.g., close to the lower voltage level of the two voltage levels at the two terminals of bidirectional switch 302), and thus bias driver circuit 350 may consume little or no quiescent current. In some examples, diodes 360 and 362 may be implemented using HEMTs and may be monolithically integrated with bidirectional switch 302 on a same semiconductor die using the same fabrication process.

In some examples, the bias circuit may be implemented using a first switch circuit (e.g., a transistor or a diode implemented using a transistor) between the first terminal (e.g., first switch terminal 306) of the bidirectional switch (e.g., bidirectional switch 302) and the reference terminal (e.g., reference terminal 352) of the driver circuit (e.g., driver circuit 350), and a second switch circuit (e.g., a transistor or a diode implemented using a transistor) between the reference terminal of the driver circuit and the second terminal (e.g., second switch terminal 308) of the bidirectional switch. The first switch circuit and the second switch circuit may be controlled by a same control signal to electrically couple (e.g., with a small voltage drop) the reference terminal of the driver circuit to a terminal of the first terminal or the second terminal that has a lower voltage level. The control signal for controlling the first switch circuit and the second switch circuit may be, for example, the output of the driver circuit or the output (e.g., the bias voltage) of the bias circuit. The first switch circuit and the second switch circuit can be implemented using, for example, small HEMTs, and thus can be monolithically integrated with the bidirectional switch formed by GaN-based HEMTs and would not take a large semiconductor area.

In one example, the bias circuit may include two transistors (e.g., small HEMTs) connected back-to-back and controlled by a delayed output of the driver circuit to provide a bias voltage level that is equal to or close to the voltage level of the virtual source or the common source of the bidirectional switch to bias the driver circuit during steady state. The delayed output of the driver circuit may switch off at least one of the two transistors of the bias circuit after the bidirectional switch have been turned off, such that any charges stored at the bidirectional switch (e.g., at the gate) can be removed through one of the two transistors and the bias voltage can be reduced, thereby ensuring that the bidirectional switch is fully turned off.

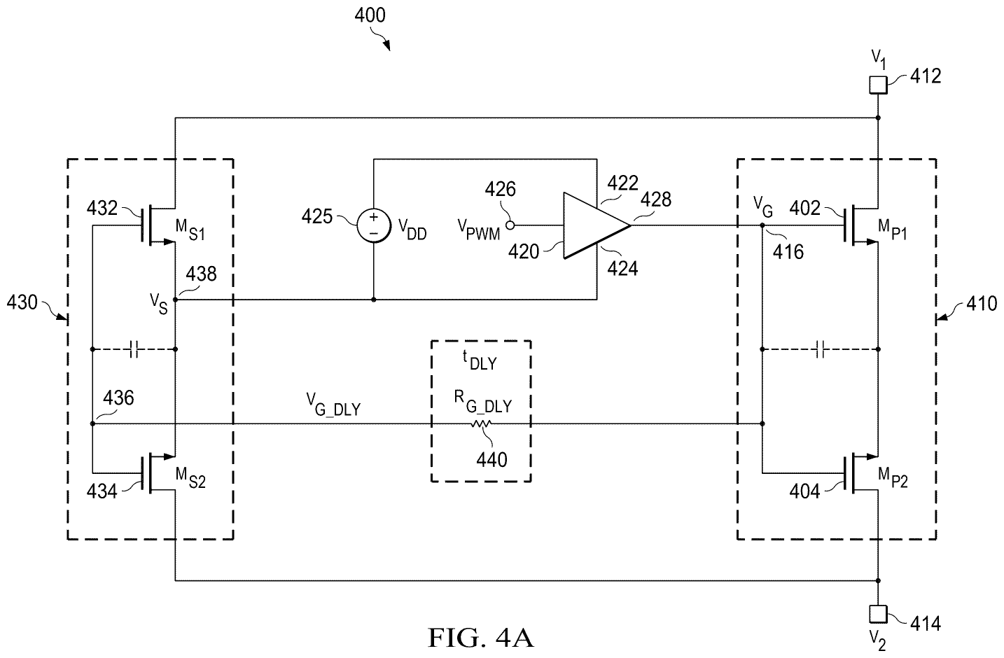

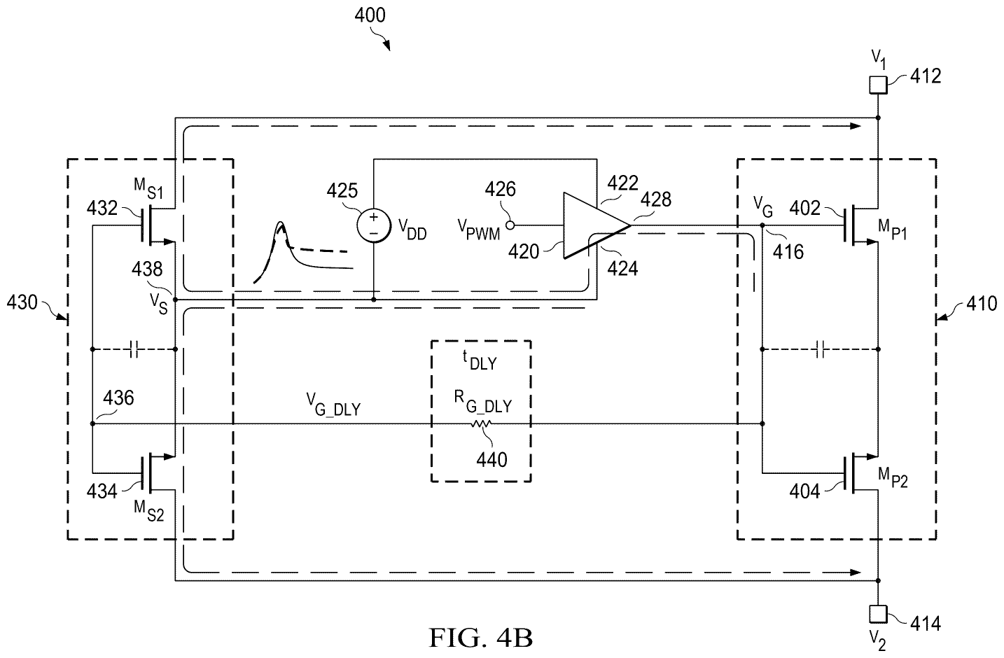

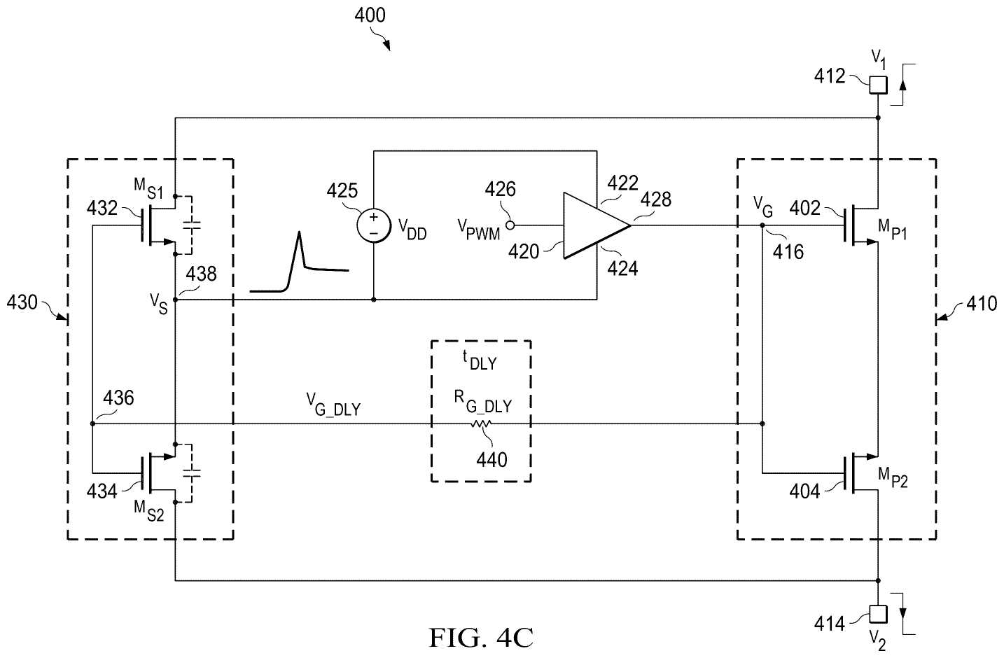

FIG. 4A is a schematic of an example of a circuit 400 including a bidirectional switch 410 and circuits for controlling bidirectional switch 410. In some examples, circuit 400 can be part of an integrated circuit including one or more semiconductor dies. Bidirectional switch 410 may be an example of dual-gate bidirectional switch 205 or an example of single-gate bidirectional switch 302 described above. Bidirectional switch 410 may include a first switch terminal 412 (which may be an input terminal and/or output terminal), a second switch terminal 414 (which may be an input terminal and/or output terminal), and a switch control terminal 416 (e.g., a gate terminal). Bidirectional switch 410 may be represented schematically by an HEMT 402 (M_{P1}) and an HEMT 404 (M_{P2}) that share a common source (either real or virtual) and, in the case of single-gate bidirectional switch, a common gate structure.

The circuits for controlling bidirectional switch 410 may include a driver circuit 420, a voltage source 425, and a bias circuit 430. In some examples, one or more of bias circuit 430, driver circuit 420, and voltage source 425 can be on the same semiconductor die and/or in the same integrated circuit package as bidirectional switch 410. In some examples, one or more of bias circuit 430, driver circuit 420, and voltage source 425 can be on a different semiconductor die from bidirectional switch 410, and/or external to the integrated circuit package containing bidirectional switch 410. Driver circuit 420 may have a power terminal 422, a reference terminal 424, a driver input 426, and a driver output 428. Driver circuit 420 may be implemented using silicon-based CMOS circuits or GaN-based circuits, and may be on the same die as bidirectional switch 410 or may be on a different die. Power terminal 422 of driver circuit 420 may be coupled to the anode of voltage source 425, and reference terminal 424 may be coupled to the cathode of voltage source 425 and a bias output 438 of bias circuit 430. Driver input 426 may be coupled to a control signal, such as a pulse-width-modulation signal. Driver output 428 may be coupled to switch control terminal 416 of bidirectional switch 410.

In the example illustrated in FIG. 4A, bias circuit 430 may have a first terminal that is coupled to first switch terminal 412, a second terminal that is coupled to second switch terminal 414, a bias control terminal 436, and bias output 438. Bias circuit 430 may include a first transistor 432 (M_{S1}) and a second transistor 434 (M_{S2}) connected back-to-back, where the sources of the two transistors may be shorted at bias output 438. First transistor 432 (M_{S1}) and second transistor 434 (M_{S2}) may be implemented using HEMTs, and may have much smaller widths than HEMT 402 (M_{P1}) and HEMT 404 (M_{P2}). For example, a width ratio between HEMT 402 (M_{P1}) and first transistor 432 (M_{S1}) may be greater than about 100, 200, 500, 1000, or more. In some examples where bidirectional switch 410 may be a dual-gate bidirectional switch, the width ratio between first transistor 432 (M_{S1}) and second transistor 434 (M_{S2}) may match the width ratio between HEMT 402 (M_{P1}) and HEMT 404 (M_{P2}). The gates of first transistor 432 (M_{S1}) and second transistor 434 (M_{S2}) may be shorted at bias control terminal 436, which may be coupled to driver output 428 directly or through a delay device 440 that may provide a delayed output of driver circuit 420 to bias control terminal 436. Delay device 440 may include, for example, a delay line or a resistor that may form an RC delay circuit with the parasitic capacitance of circuit 400 (e.g., parasitic capacitors at the gates of the transistors).

In circuit 400, when the voltage difference between the voltage level at driver output 428 and the voltage level at the common source (or the voltage level at the drain of HEMT 402 or HEMT 404 if the common source is a virtual source) is greater than the threshold voltage of the HEMT, such as about 5V or higher, HEMT 402 and HEMT 404 may be turned on such that bidirectional switch 410 may be switched from an OFF state to an ON state. The voltage level at the common source may be closer to the lower one of the voltage level at first switch terminal 412 and the voltage level at second switch terminal 414. First transistor 432 (M_{S1}) and second transistor 434 (M_{S2}) may also be turned on by the delayed output of driver circuit 420. The voltage level at bias output 438 may be similar to or same as the voltage level at the virtual or phantom common source of bidirectional switch 410. For example, the voltage level at bias output 438 may be equal to the sum of the lower voltage level of the two voltage levels at first switch terminal 412 and second switch terminal 414 and the voltage drop in first transistor 432 (M_{S1}) or second transistor 434 (M_{S2}), which may be close to zero due to the small on-state resistance of HEMTs.

In examples where bidirectional switch 410 may be a dual-gate bidirectional switch and the width ratio between first transistor 432 (M_{S1}) and second transistor 434 (M_{S2}) may match the width ratio between HEMT 402 (M_{P1}) and HEMT 404 (M_{P2}), the voltage level at bias output 438 may be the same as the voltage level at the common source of HEMT 402 (M_{P1}) and HEMT 404 (M_{P2}) in bidirectional switch 410, because of the same voltage dividing ratio for dividing the voltage difference between first switch terminal 412 and second switch terminal 414. Therefore, using the voltage level at bias output 438 to bias driver circuit 420 for driving the dual-gate bidirectional may be appropriate.

In examples where bidirectional switch 410 may be a single-gate bidirectional switch without a physical common source, the voltage level at bias output 438 may be close to the lower voltage level of the two voltage levels at first switch terminal 412 and second switch terminal 414 due to the small on-state resistance and thus small voltage drop in first transistor 432 (M_{S1}) or second transistor 434 (M_{S2}). The (theoretical) voltage level at the virtual common source of bidirectional switch 410 may also be close to the lower one of the two voltage levels at first switch terminal 412 and second switch terminal 414 due to the small on-state resistance and thus small voltage drop in the single-gate bidirectional switch. As such, using the voltage level at bias output 438 to bias driver circuit 420 for driving the single-gate bidirectional switch may be appropriate.

After bidirectional switch 410 is turned off, first transistor 432 (M_{S1}) and second transistor 434 (M_{S2}) may also be turned off (e.g., after a delay), and the voltage level at bias output 438 may remain close to the lower one of the two voltage levels at first switch terminal 412 and second switch terminal 414, and thus may continue to bias driver circuit 420 properly, while consuming little or no quiescent current.

When bidirectional switch 410 is turned off, if first transistor 432 (M_{S1}) and second transistor 434 (M_{S2}) are turned off at the same time as bidirectional switch 410, the charges stored at the gate (e.g., switch control terminal 416) of bidirectional switch 410 may cause the voltage level at bias output 438 to increase. Since first transistor 432 (M_{S1}) and second transistor 434 (M_{S2}) are turned off, there may not be a current path to remove the stored charges at bias output 438 to reduce the voltage of bias output 438 to the lower level of the two voltage levels at first switch terminal 412 and second switch terminal 414. Therefore, the voltage level at bias output 438 and reference terminal 424 may remain higher than the lower one of the two voltage levels at first switch terminal 412 and second switch terminal 414. Because driver circuit 420 may be biased by a voltage level that may be higher than the voltage level of the common source (real or virtual) of bidirectional switch 410, the output at driver output 428 of driver circuit 420 may be higher than the desired level and thus may not fully turn off bidirectional switch 410.

FIG. 4B is a schematic illustrating an example of an operation of circuit 400 of FIG. 4A. As illustrated, when bidirectional switch 410 is turned off, the charges at the gate (and switch control terminal 416) of bidirectional switch 410 may cause the voltage level at bias output 438 to increase initially. Because there is a delay device 440 between driver output 428 and bias control terminal 436, first transistor 432 (M_{S1}) and second transistor 434 (M_{S2}) may remain in the ON state for a period after bidirectional switch 410 is turned off, such that the stored charges may be removed through first transistor 432 (M_{S1}) or second transistor 434 (M_{S2}) to a lower voltage level at first switch terminal 412 or second switch terminal 414, to set the voltage level at bias output 438 and reference terminal 424 to a level close to the lower voltage level at either first switch terminal 412 or second switch terminal 414. In this way, driver circuit 420 may be properly biased and may provide proper output to switch control terminal 416 to fully turn off bidirectional switch 410.

FIG. 4C is a schematic illustrating an example of an operation of circuit 400 of FIG. 4A. In circuit 400, when bidirectional switch 410 is turned off, if there is a large voltage change during a short time period (and thus a high dV/dt) at first switch terminal 412 or second switch terminal 414, the voltage level at bias output 438 (and reference terminal 424) may also change (e.g., increase) due to, for example, capacitive coupling caused by the parasitic capacitance of first transistor 432 (M_{S1}) and/or second transistor 434 (M_{S2}). When the dV/dt is higher, the voltage level at bias output 438 may be higher. Since first transistor 432 (M_{S1}) and second transistor 434 (M_{S2}) are turned off by the delayed output of the driver output, the voltage level at bias output 438 (and reference terminal 424) may not be reduced to a level close to the lower voltage level at either first switch terminal 412 or second switch terminal 414. Therefore, driver circuit 420 may not be properly biased and the output at driver output 428 may turn on bidirectional switch 410.

In some example, this undesired effect caused by the high dV/dt may be mitigated by reducing the threshold voltage of the diode structure formed by first transistor 432 (M_{S1}) or second transistor 434 (M_{S2}) so that the voltage increase at bias output 438 may cause the diode structure formed by first transistor 432 (M_{S1}) or second transistor 434 (M_{S2}) to turn on, thereby causing the voltage level at bias output 438 to reduce due to the discharging to a lower voltage level. The diode structure formed by the transistor with a lower threshold voltage may cause a lower voltage drop across the diode, such that the voltage level at bias output 438 may be closer to the lower voltage level at either first switch terminal 412 or second switch terminal 414. However, it can be difficult and expensive to achieve the low threshold voltage in first transistor 432 (M_{S1}) and second transistor 434 (M_{S2}).

According to some examples disclosed herein, the integrated circuit may include a high-pass circuit between the two terminals of the bidirectional switch to ensure that the bidirectional switch remains in the OFF state when the voltage level at a terminal of the bidirectional switch changes at a fast rate (e.g., with a high dV/dt). The high-pass circuit may include a high-pass filter, and two transistors (e.g., small HEMTs) coupled between the two terminals of the bidirectional switch. When a voltage level at a terminal of the bidirectional switch changes at a fast rate (e.g., with a high dV/dt), the high-pass filter may generate (e.g., via capacitive coupling) a voltage signal to drive the gates of the two transistors, so that at least one of the two transistors may be turned on to provide the lower voltage level at the two terminals of the bidirectional switch to the gate of the bidirectional switch, thereby ensuring that the bidirectional switch remains in the OFF state during a voltage change at a high dV/dt, without using transistors with low threshold voltages in the bias circuit. The high-pass circuit can also provide a current path to remove the charges stored at the high-pass circuit due to the voltage change at the high dV/dt, to ensure that the two transistors of the high-pass circuit are turned off and would not consume power during the steady state.

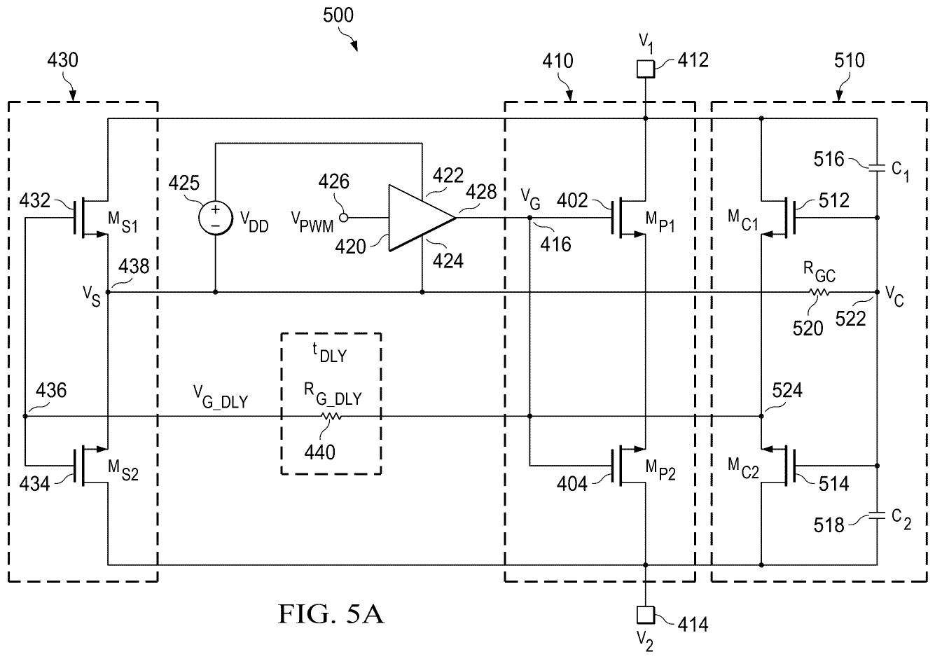

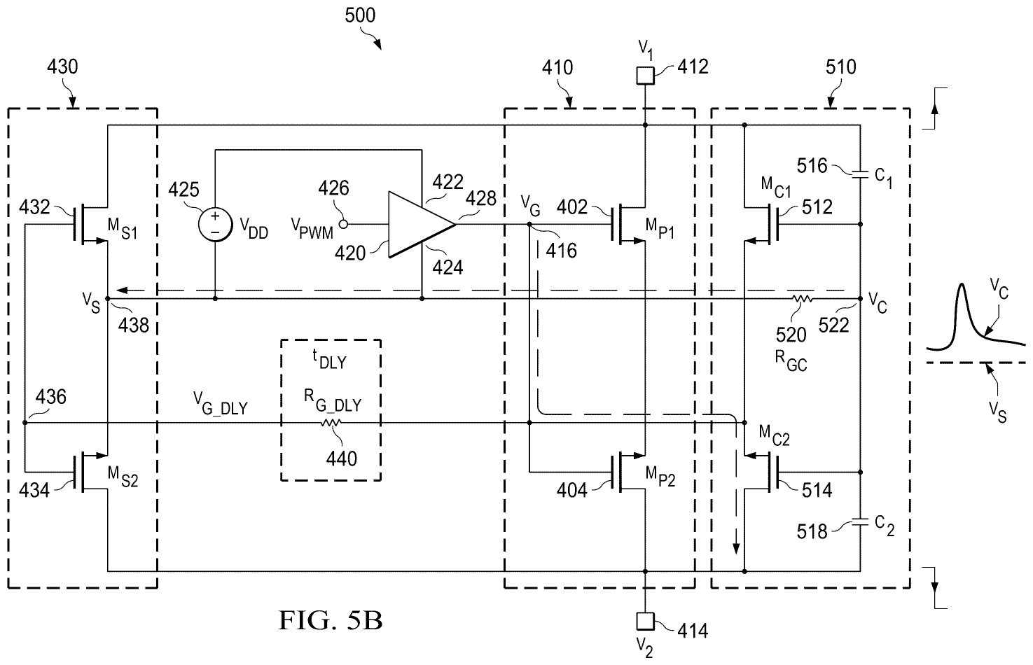

FIG. 5A is a schematic of an example of a circuit 500 including bidirectional switch 410 and circuits for controlling bidirectional switch 410. Circuit 500 may include one or more semiconductor dies. Circuit 500 may include circuit 400 and an additional high-pass circuit 510 to keep bidirectional switch 410 in the off state during high dV/dt. Devices and circuits of circuit 400 are described above with respect to FIGS. 4A-4C, and thus are not described again with respect to FIG. 5A. High-pass circuit 510 may include a transistor 512 (M_{C1}), a transistor 514 (M_{C2}), a capacitor 516 (C1), a capacitor 518 (C2), and a resistor 520 (R_{GC}). Transistor 512 and transistor 514 may be small HEMTs and can be integrated with bidirectional switch 410 and bias circuit 430 on a same semiconductor die using the same fabrication process. In some examples, transistor 512 and transistor 514 are on a different die from bidirectional switch 410 and/or bias circuit 430. In some examples, driver circuit 420 may also be on the semiconductor die that includes bidirectional switch 410, bias circuit 430, and/or high-pass circuit 510. In some examples, driver circuit 420 may also be on a silicon-based die. Capacitor 516, capacitor 518, and resistor 520 may form a high-pass filter.

As illustrated, the drain of transistor 512 (M_{C1}) may be coupled to first switch terminal 412, the source of transistor 512 (M_{C1}) may be coupled to the source of transistor 514 (M_{C2}) at a node 524, and the drain of transistor 514 (M_{C2}) may be coupled to second switch terminal 414. The source of transistor 512 and the source of transistor 514 may be coupled to switch control terminal 416 of bidirectional switch 410 and driver output 428. Capacitor 516 may be coupled to first switch terminal 412 and the gate of transistor 512. Capacitor 518 may be coupled to second switch terminal 414 and the gate of transistor 514. The gate of transistor 512 and the gate of transistor 514 may be shorted at a node 522 and may be coupled to bias output 438 and reference terminal 424 through resistor 520. Resistor 520 may have a high resistance.

FIG. 5B is a schematic illustrating examples of operations of circuit 500 of FIG. 5A. As shown in FIG. 5B, when a large voltage change occurs during a short time period (e.g., at a high dV/dt) at first switch terminal 412 or second switch terminal 414, the high dV/dt may cause the voltage level at node 522 (and the gate of transistor 512 and the gate of transistor 514) to increase due to capacitive coupling through capacitors 516 and/or 518. When the voltage level at node 522 is sufficiently high, at least one of transistor 512 or transistor 514 may be turned on to set the voltage level at the source of transistor 512 and the source of transistor 514 to a level close to the lower one of the two voltage levels at first switch terminal 412 and second switch terminal 414. Because switch control terminal 416 of bidirectional switch 410 and driver output 428 are coupled to the source of transistor 512 and the source of transistor 514, the voltage level at switch control terminal 416 may also be close to the lower one of the two voltage levels at first switch terminal 412 and second switch terminal 414. Therefore, both HEMT 402 (M_{P1}) and HEMT 404 (M_{P2}) may remain in the OFF state. As such, when bidirectional switch 410 is in the OFF state, a high dV/dt at first switch terminal 412 or second switch terminal 414 may not cause bidirectional switch 410 to turn on as described above with respect to FIG. 4C, even when first transistor 432 (M_{S1}) and second transistor 434 (M_{S2}) have high threshold voltages.

Node 522 may be gradually discharged through resistor 520 and, for example, first transistor 432 (M_{S1}) or second transistor 434 (M_{S2}). Therefore, during a steady state, the voltage level at node 522 may be close to the voltage level at bias output 438, which may be close to the lower one of the two voltage levels at first switch terminal 412 and second switch terminal 414. Therefore, both transistor 512 and transistor 514 may be turned off in the steady state and may not consume power.

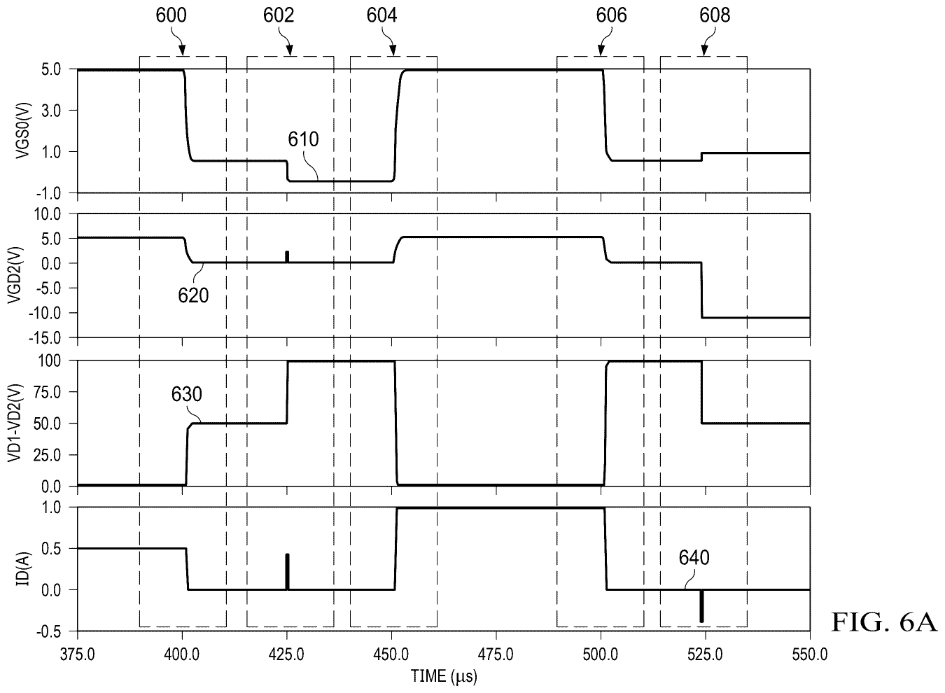

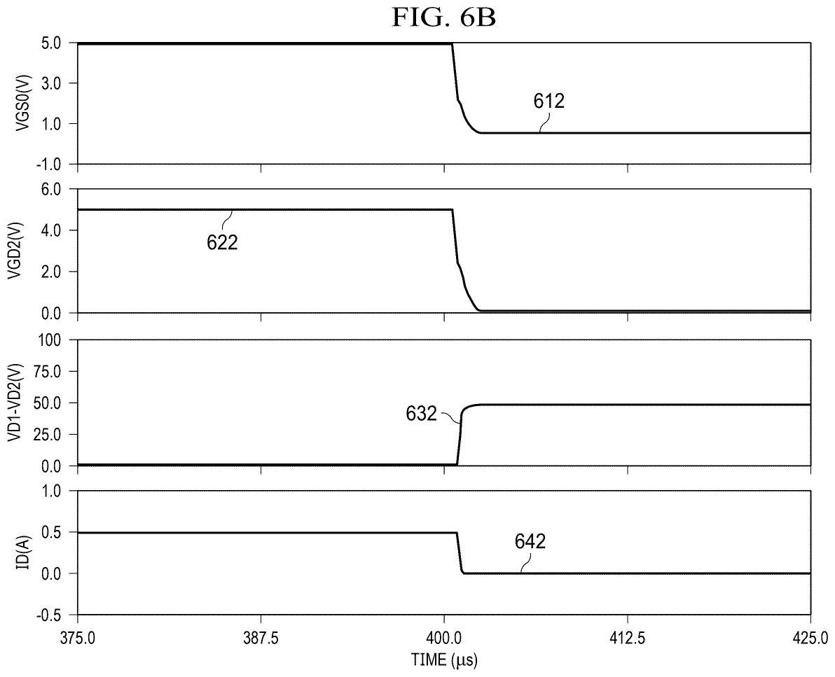

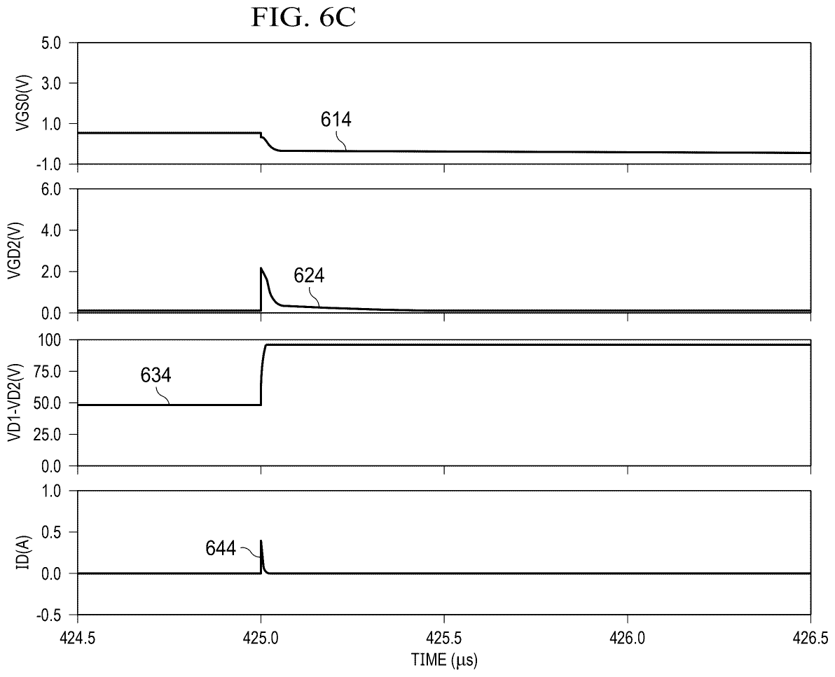

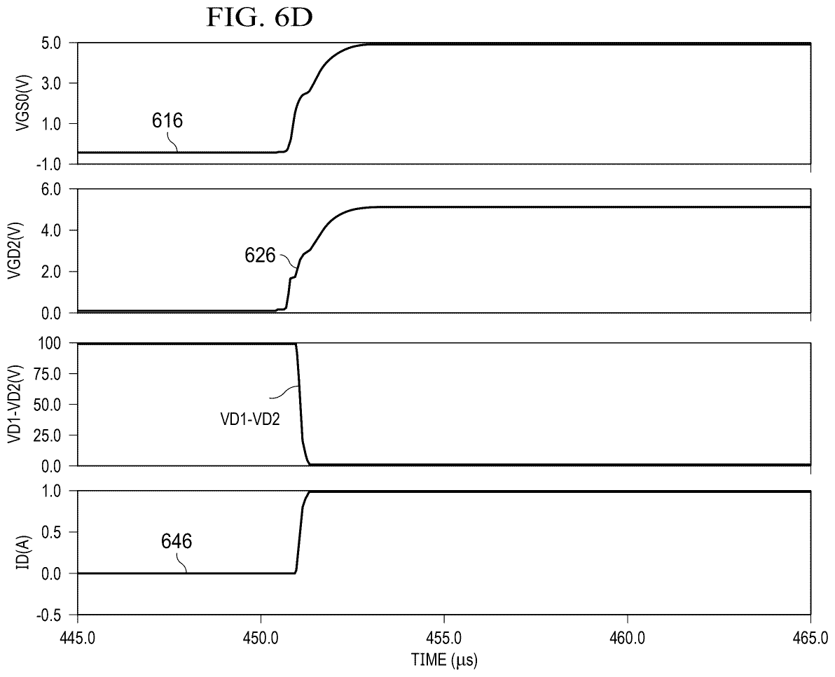

FIG. 6A includes a graph illustrating examples of simulated waveforms of some signals of circuit 500 of FIG. 5A during switching operations. For example, during a first time period 600, bidirectional switch 410 may be turned off from the ON state. During a second time period 602, the voltage difference between first switch terminal 412 and second switch terminal 414 may be increased quickly (e.g., at a dV/dt about 50 V/ns) while bidirectional switch 410 is in the OFF state. During a third time period 604, bidirectional switch 410 may be turned on from the OFF state while the voltage difference between first switch terminal 412 and second switch terminal 414 remains high. During a fourth time period 606, bidirectional switch 410 may be turned off from the ON state. During a fifth time period 608, the voltage difference between first switch terminal 412 and second switch terminal 414 may be decreased quickly (e.g., at a dV/dt about −50 V/ns) while bidirectional switch 410 is in the OFF state. In the simulations, the voltage level V₂ (or drain voltage V_{D2} of HEMT 404) at second switch terminal 414 may be lower than the voltage level V₁ (or drain voltage V_{D1} of HEMT 402) at first switch terminal 412.

FIG. 6A shows a waveform 610 illustrating the voltage difference Vaso between switch control terminal 416 (e.g., gate structure 340 or control terminal 304) of bidirectional switch 410 and the virtual common source of bidirectional switch 410. A waveform 620 shows the voltage difference V_{GD2} between switch control terminal 416 (e.g., gate structure 340 or control terminal 304) of bidirectional switch 410 and the drain of HEMT 404 (M_{P2}) (and second switch terminal 414). A waveform 630 shows the voltage difference V_{D1}−V_{D2} between first switch terminal 412 and second switch terminal 414. A waveform 640 shows a current I_{D} between first switch terminal 412 and second switch terminal 414.

FIG. 6B is a zoom-in view of the simulated waveforms of FIG. 6A in first time period 600 when bidirectional switch 410 is turned off. At the start of first time period 600, the voltage level at switch control terminal 416 may be at a high level, such that the voltage difference V_{GD2} may be greater than the threshold voltage of bidirectional switch 410. Therefore, bidirectional switch 410 may be in the ON state, and the virtual common source of bidirectional switch 410 may be close to the voltage level at second switch terminal 414 (e.g., about 0 V). In the illustrated example, the voltage difference Vaso may be about 5V as shown by a waveform 612, the voltage difference V_{GD2} may also be about 5V as shown by a waveform 614, the current I_{D} flowing from first switch terminal 412 to second switch terminal 414 may be high as shown by a waveform 642, and the voltage difference V_{D1}−V_{D2} may be close to 0V as shown by a waveform 632 due to the low on-state resistance and thus no voltage drop of bidirectional switch 410.

When the voltage level at switch control terminal 416 is changed from the high level to a low level, the voltage difference V_{GD2} may be close to zero as shown by waveform 622, and thus bidirectional switch 410 may be turned off. When bidirectional switch 410 is turned off, the current I_{D} flowing from first switch terminal 412 to second switch terminal 414 may be close to zero as shown by waveform 642, the virtual common source may be floating and thus the voltage difference Vaso may be either higher or lower than zero as shown by waveform 612, and first switch terminal 412 and second switch terminal 414 may be disconnected from each other such that the voltage difference V_{D1}−V_{D2} may be high (e.g., about 50 V in the illustrated example) as shown by waveform 632.

FIG. 6C is a zoom-in view of the simulated waveforms of FIG. 6A in second time period 602 when the voltage difference between the two terminals of bidirectional switch 410 increases quickly while bidirectional switch 410 is in the OFF state. When bidirectional switch 410 is in the OFF state, the voltage level at switch control terminal 416 may be at a low level, the voltage difference V_{GD2} may be close to zero as shown by waveform 624, the current I_{D} between first switch terminal 412 and second switch terminal 414 may be close to zero as shown by a waveform 644, the virtual common source may be floating and thus the voltage difference Vaso may be either higher or lower than zero as shown by waveform 614, and the voltage difference V_{D1}−V_{D2} may be high (e.g., about 50 V in the illustrated example) as shown by waveform 634.

When the voltage level at first switch terminal 412 quickly increases (e.g., changing from about 50 V to about 100 V in about 1 ns), the voltage difference V_{D1}−V_{D2} may increase quickly as shown by waveform 634, and a voltage spike may occur at switch control terminal 416 as shown by waveform 624, due to, for example, the capacitive coupling between the drain and gate of HEMT 402 (M_{P1}) or HEMT 404 (M_{P2}). As described above with respect to FIGS. 5A and 5B, when the voltage level at first switch terminal 412 increases quickly, the voltage level at node 522 may be sufficiently high to turn on at least transistor 514, such that the voltage level at node 524 and switch control terminal 416 may be set to a level close to the voltage level at second switch terminal 414 (e.g., about 0 V) as shown by waveform 624. Waveform 644 shows a spike in current I_{D}, which may be caused by the capacitive coupling. Current I_{D} may reduce to about zero after high-pass circuit 510 in circuit 500 settles as shown by waveform 644.

FIG. 6D is a zoom-in view of the simulated waveforms of FIG. 6A in third time period 604 when bidirectional switch 410 is turned on. In third time period 604, the voltage level at switch control terminal 416 may be changed from a low level to a high level to turn on HEMT 402 (M_{P1}), HEMT 404 (M_{P2}), first transistor 432 (M_{S1}), and a second transistor 434 (M_{S2}). Thus, voltage level at bias output 438 and the voltage level at the virtual common source may gradually settle to a level close to the voltage level at second switch terminal 414 (e.g., about 0V). Therefore, the voltage difference Vaso may gradually settle to a high level (e.g., close to 5 V in the illustrated example) as shown by a waveform 616, and the voltage difference V_{GD2} may gradually settle to a high level (e.g., about 5 V in the illustrated example) as shown by a waveform 626. When bidirectional switch 410 is turned on, the current ID may be high as shown by a waveform 646, the voltage drop on bidirectional switch 410 may be low due to the low on-state resistance of bidirectional switch 410, and thus the voltage level at first switch terminal 412 may be close to the voltage level at second switch terminal 414, such that the voltage difference V_{D1}−V_{D2} may be close to zero as shown by a waveform 636.

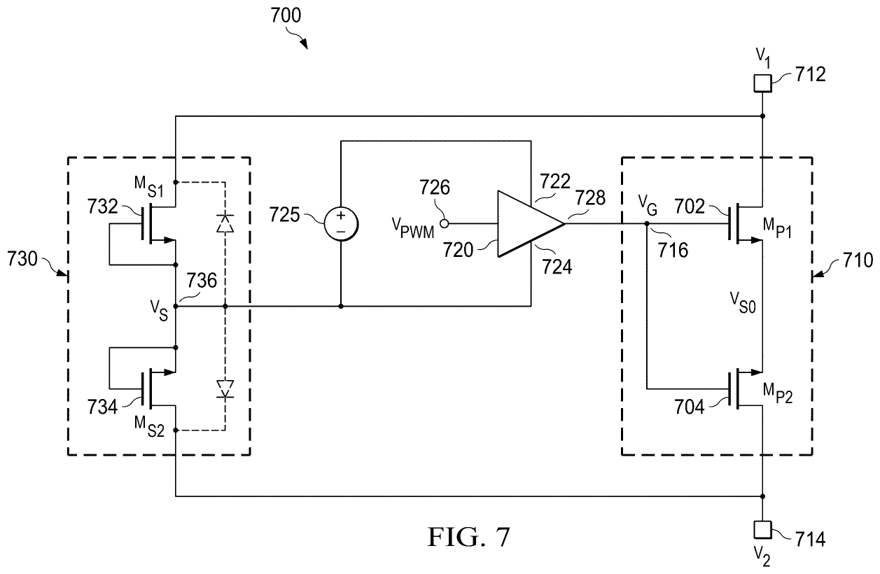

FIG. 7 is a schematic of an example of a circuit 700 including a bidirectional switch 710 and circuits for controlling bidirectional switch 710. Circuit 700 may include one or more semiconductor dies. Bidirectional switch 710 may be similar to bidirectional switch 410, and may be an example of dual-gate bidirectional switch 205 or single-gate bidirectional switch 302 described above. The circuits for controlling bidirectional switch 710 may include a driver circuit 720 (which may be similar to driver circuit 420), a voltage source 725 (which may be similar to voltage source 425), and a bias circuit 730. In some examples, one or more of bias circuit 730, driver circuit 720, and voltage source 725 can be on the same semiconductor die and/or in the same integrated circuit package as bidirectional switch 710. In some examples, one or more of bias circuit 730, driver circuit 720, and voltage source 725 can be on a different semiconductor die from bidirectional switch 710, and/or external to the integrated circuit package containing bidirectional switch 710.

Bidirectional switch 710 may have a first switch terminal 712 (which may be an input terminal and/or output terminal), a second switch terminal 714 (which may be an input terminal and/or output terminal), and a control terminal 716 (e.g., a gate terminal). Bidirectional switch 710 may be represented by an HEMT 702 (M_{P1}) and an HEMT 704 (M_{P2}) that share a common source (either real or virtual) and, in the case of single-gate bidirectional switch, a common gate structure.

Driver circuit 720 may have a power terminal 722, a reference terminal 724, a driver input 726, and a driver output 728. Driver circuit 720 may be implemented using silicon-based CMOS circuits or GaN-based circuits. Power terminal 722 of driver circuit 720 may be coupled to the anode of voltage source 725, and reference terminal 724 may be coupled to the cathode of voltage source 725 and output of bias circuit 730. Driver input 726 may be coupled to a control signal, such as a pulse-width-modulation signal. Driver output 728 may be coupled to control terminal 716 of bidirectional switch 710.

In the example illustrated in FIG. 7, bias circuit 730 may have a first terminal that is coupled to first switch terminal 712, a second terminal that is coupled to second switch terminal 714, and a bias output 736. Bias circuit 730 may include a first transistor 732 (M_{S1}) and a second transistor 734 (M_{S2}) connected back-to-back. First transistor 732 (M_{S1}) and second transistor 734 (M_{S2}) may be implemented using HEMTs, and may have much smaller widths than HEMT 702 (M_{P1}) and HEMT 704 (M_{P2}) (e.g., with a width ratio of 1:100, 1:500, 1:1000, etc.). The source and the gate of each of first transistor 732 (M_{S1}) and second transistor 734 (M_{S2}) may be shorted at bias output 736 to form a diode structure. Therefore, bias circuit 730 may have two diodes connected back-to-back, where the anodes of the diodes are coupled together at bias output 736.

The voltage level Vs at bias output 736 may be set to a voltage level that is equal to the sum of the voltage drop across a diode and the lower voltage level of the two voltage levels at first switch terminal 712 and second switch terminal 714. For example, if the voltage level V₂ at second switch terminal 714 is lower than the voltage level V₁ at first switch terminal 712, the voltage level Vs at bias output 736 may be set to a voltage level that is equal to the sum of the voltage drop across the diode structure formed by second transistor 734 (M_{S2}) and the voltage level V₂ at second switch terminal 714. However, when bidirectional switch 710 is turned on, the voltage drop across bidirectional switch 710 may be low, and thus the voltage level V_{S0} at the virtual common source of bidirectional switch 710 may be close to the lower voltage level of the two voltage levels at first switch terminal 712 and second switch terminal 714. Therefore, the voltage level Vs at bias output 736 may be higher than the voltage level V_{S0} at the virtual common source of bidirectional switch 710. When the threshold voltages of first transistor 732 (M_{S1}) and second transistor 734 (M_{S2}) is high, the voltage difference between the voltage level Vs at bias output 736 and the voltage level V_{S0} at the virtual common source of bidirectional switch 710 may be large, which may cause the output at driver output 728 to be high enough to turn on bidirectional switch 710. To ensure that the voltage level Vs at bias output 736 is close to the voltage level V_{S0} at the virtual common source of bidirectional switch 710 so that driver circuit 720 may fully turn off bidirectional switch 710, it may be desirable that the threshold voltages of (and thus the voltage drop across) the diodes formed by first transistor 732 (M_{S1}) and second transistor 734 (M_{S2}) are low.

When bidirectional switch 710 and the two diodes formed by first transistor M_{S1} (732) and second transistor 734 (M_{S2}) are turned off, the bias voltage at bias output 736 and reference terminal 724 may remain unchanged (e.g., close to the sum of the voltage drop across a diode and the lower voltage level of the voltage levels at the two switch terminals of bidirectional switch 710), and thus can bias driver circuit 720 while consuming little quiescent current.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. An integrated circuit comprising:
a driver circuit having a driver input, a driver output, a power terminal, and a reference terminal; and
a bias circuit having a first terminal, a second terminal, a bias control terminal, and a bias output, the bias output coupled to the reference terminal, the bias circuit including a first transistor coupled between the first terminal and the bias output and a second transistor coupled between the bias output and the second terminal, the first transistor having a first control terminal, and the second transistor having a second control terminal, wherein the first control terminal and the second control terminal are coupled to the bias control terminal to receive a same control signal from the bias control terminal.

2. The integrated circuit of claim 1, wherein the bias control terminal is electrically coupled to the driver output.

3. The integrated circuit of claim 2, further comprising a resistor coupling the bias control terminal to the driver output.

4. The integrated circuit of claim 1, further comprising a voltage source coupled between the bias output of the bias circuit and the power terminal of the driver circuit.

5. The integrated circuit of claim 1, further comprising a bi-directional switch coupled between the first terminal and the second terminal, the bi-directional switch having a bi-directional switch control terminal coupled to the driver output.

6. The integrated circuit of claim 5, wherein the bi-directional switch includes at least one high electron mobility transistor (HEMT).

7. The integrated circuit of claim 5, wherein the bi-directional switch includes:
a single gate structure coupled to the bi-directional switch control terminal;
a first switch terminal coupled to the first terminal; and
a second switch terminal coupled to the second terminal.

8. The integrated circuit of claim 5, wherein:
the bi-directional switch includes a third transistor and a fourth transistor serially connected between the first terminal and the second terminal; and
the bi-directional switch control terminal is coupled to both a third control terminal of the third transistor and a fourth control terminal of the fourth transistor.

9. The integrated circuit of claim 8, wherein a first width ratio between the third transistor and the first transistor matches a second width ratio between the fourth transistor and the second transistor.

10. The integrated circuit of claim 9, wherein the first width ratio is greater than 100.

11. The integrated circuit of claim 5, wherein the bias circuit and the bi-directional switch are in a same semiconductor die.

12. The integrated circuit of claim 1, further comprising:
a third transistor coupled between the first terminal and the driver output, the third transistor having a third control terminal;
a fourth transistor coupled between the second terminal and the driver output, the fourth transistor having a fourth control terminal coupled to the third control terminal;
a first capacitor coupled between the first terminal and the third control terminal; and
a second capacitor coupled between the second terminal and the fourth control terminal.

13. The integrated circuit of claim 12, wherein the third control terminal and the fourth control terminal are coupled to the bias output of the bias circuit through a resistor.

14. The integrated circuit of claim 12, wherein a first width ratio between the third transistor and the first transistor matches a second width ratio between the fourth transistor and the second transistor.

15. The integrated circuit of claim 1, wherein the bias control terminal is coupled to the bias output.

16. An integrated circuit comprising:
a bi-directional switch coupled between a first terminal and a second terminal, the bi-directional switch having a switch control terminal;
a driver circuit having a reference terminal and a driver output, the driver output coupled to the switch control terminal; and
a bias circuit coupled between the first terminal and the second terminal, the bias circuit having a bias output coupled to the reference terminal,
wherein the bi-directional switch and the bias circuit are on a semiconductor die.

17. The integrated circuit of claim 16, wherein the bias circuit comprises:
a first transistor coupled between the first terminal and the bias output, the first transistor having a first control terminal electrically coupled to the driver output; and
a second transistor coupled between the bias output and the second terminal, the second transistor having a second control terminal electrically coupled to the driver output.

18. The integrated circuit of claim 17, wherein the first control terminal and the second control terminal are electrically coupled to the driver output through a delay circuit.

19. The integrated circuit of claim 17, further comprising:
a third transistor coupled between the first terminal and the driver output, the third transistor having a third control terminal electrically coupled to the bias output;
a fourth transistor coupled between the second terminal and the driver output, the fourth transistor having a fourth control terminal electrically coupled to the bias output;
a first capacitor coupled between the first terminal and the third control terminal; and
a second capacitor coupled between the second terminal and the fourth control terminal.

20. An integrated circuit comprising:
a driver circuit for driving a bidirectional switch between a first terminal and second terminal, the driver circuit having a reference terminal and a driver output; and
a bias circuit including a first switch circuit between the first terminal and the reference terminal and a second switch circuit between the reference terminal and the second terminal, wherein the first switch circuit and the second switch circuit are controlled by a same control signal to electrically couple the reference terminal to a lower voltage level of two voltage levels at the first terminal and the second terminal.
